(19) United States
(12) Patent Application Publication
(10) Pub. No.: US 2015/0027541 A1
(43) Pub. Date: Jan. 29, 2015

(54) ELECTRONIC COMPONENT WITH MOISTURE BARRIER LAYER

(71) Applicant: OSRAM Opto Semiconductors GmbH, Regensburg (DE)

(72) Inventors: Richard Baisl, Regensburg (DE); Michael Popp, Freising (DE); Tilman Schlenker, Nittendorf (DE); Erwin Lang, Regensburg (DE); Evelyn Trummer-Sailer, Mintraching (DE)

(73) Assignee: OSRAM Opto Semiconductors GmbH, Regensburg (DE)

(21) Appl. No.: 14/384,165

(22) PCT Filed: Mar. 13, 2013
(86) PCT No.: PCT/EP2013/055130

§ 371 Date: Sep. 10, 2014

(30) Foreign Application Priority Data
Mar. 16, 2012 (DE) 102012204150.8

(51) Int. Cl. H01L 51/44; H01L 51/56; H01L 51/52

(52) U.S. Cl. CPC H01L 51/448; H01L 51/5256; H01L 51/56
USPC 136/263; 257/40; 438/22

(57) ABSTRACT

Various embodiments may relate to an electronic component including a layer to be protected against moisture, and a moisture barrier layer arranged at least partly on or above and/or below the layer to be protected. The moisture bather layer includes a plurality of layers composed of the same material having different stoichiometric compositions.

### RELATED APPLICATIONS

The present application is a national stage entry according to 35 U.S.C. §371 of PCT application No.: PCT/EP2013/055130 filed on Mar. 13, 2013, which claims priority from German application No.: 10 2012 204 150.8 filed on Mar. 16, 2012, and is incorporated herein by reference in its entirety.

### TECHNICAL FIELD

Various embodiments relate to an electronic component and to a method for producing such an electronic component.

### BACKGROUND

In a conventional electronic component, for example a conventional organic light-emitting diode (OLED), a barrier layer is usually applied for protecting moisture-sensitive and/or oxygen-sensitive regions and serves primarily to protect against the penetration of moisture and/or corrosion in order to be able to maintain its functionality in everyday use even for years and thus to enable a long service life. For this purpose, silicon nitride (SiN) or silicon oxide (SiO₂) is usually applied as a barrier layer. However, conventional barrier layers exhibit relatively high mechanical stress, which, in the case of surface structures that do not run in a planar fashion, for example, can easily lead to cracking at edges or steps, for example, which significantly reduces the barrier effect of the barrier layer and thus the service life of the electronic component. A conventional or poor barrier layer can lead to failure (occurrence of a so-called dark spot) of the component as a result of a shortened storage life of the component.

### SUMMARY

In various embodiments, an electronic component is provided in which the barrier effect of the barrier layer may be increased. Furthermore, in various embodiments, an electronic component is provided in which the storage life of the electronic component may be lengthened in a simple manner.

In various embodiments, an electronic component is provided including a layer to be protected against moisture; and a moisture barrier layer arranged at least partly on or above and/or also below the layer to be protected; wherein the moisture barrier layer includes a plurality of layers composed of the same material having different stoichiometric compositions.

Illustratively, it is possible to use the layer structure in various embodiments, for example in an optically light-emitting component, for example a bottom emitter or a top emitter or a top and bottom emitter, for example in a transparent organic light-emitting diode, wherein the layer structure in various embodiments can increase the transparency of the light-emitting component. This can be achieved in various embodiments, without significantly increasing the total thickness of the light-emitting component.

The individual layers of the layer structure of the moisture barrier layer can have different properties, for example different layer stresses. Preferably, the individual layers can be deposited one on top of another with fluid transitions between the layers. It is advantageous for the combined layers to have different layer stresses since, as a result, particles or unevennesses on the surface, for example of a layer of the electronic component that is to be protected against moisture, can be reshaped in a stress-free fashion, since strains of the support or of the subsequent layers can be adapted in an optimized manner in order to produce an overall layer that is as free of stress as possible. The moisture barrier layer exhibits a significantly improved barrier effect.

In a further configuration, the moisture barrier layer can have a layer thickness in a range of approximately 5 nm to approximately 100 μm, and in particular a layer thickness in a range of approximately 50 nm to approximately 5 μm.

In a further configuration, each layer of the plurality of layers can have a layer thickness in a range of approximately 5 nm to approximately 400 nm.

In another configuration, each layer of the plurality of layers can have for example a layer thickness of approximately 100 nm. In various embodiments, each layer of the plurality of layers can have for example a layer thickness of approximately 200 nm. In yet another configuration, each layer of the plurality of layers can have for example a layer thickness of approximately 250 nm.

In another configuration, at least one first layer of the plurality of layers can have for example a layer thickness of approximately 100 nm and at least one further layer can have a layer thickness of approximately 200 nm. In various embodiments, at least one first layer of the plurality of layers can have a layer thickness of approximately 100 nm and at least one further layer can have a layer thickness of approximately 250 nm.

In another configuration, the plurality of layers can consist of silicon nitride. In various embodiments, the silicon nitride can be amorphous and have a stoichiometric composition in accordance with the formula SiNₓ, where 0≦x<2 holds true for x.

In a further configuration, the plurality of layers can consist of silicon dioxide. In various embodiments, the silicon dioxide can be amorphous.

By way of example, at least one layer of the plurality of layers can consist of silicon nitride. Expressed illustratively, by way of example, one layer of the plurality of layers can consist of silicon nitride and at least one further layer of the plurality of layers can consist of silicon dioxide, for example.

In various embodiments, by way of example, a first layer of the plurality of layers can consist of silicon dioxide and each further layer can consist of silicon nitride.

In various embodiments, by way of example, conversely too, a first layer can consist of silicon nitride, and wherein each further layer can consist of silicon dioxide. Further layer sequences of the plurality of layers which consist alternately of silicon nitride and silicon oxide are also conceivable. By way of example, it is also possible for a first layer to consist of silicon nitride and at least one further layer to consist of silicon dioxide and at least one further layer to consist of silicon nitride again. Conversely, it is also possible for a first layer to consist of silicon dioxide, at least one further layer to consist of silicon nitride and at least one further layer to consist of silicon dioxide. It should be pointed out that examples of the sequence of the layers are purely by way of example and not exhaustive.

In various embodiments, the electronic component can include a carrier, wherein the layer to be protected against moisture can be arranged on or above the carrier, and an encapsulation, wherein the encapsulation can be arranged on or above and/or below the moisture barrier layer.

In various embodiments, the electronic component can furthermore include an encapsulation, wherein the encapsulation can be arranged on that side of the electrically active region which faces away from the substrate, and wherein the layer structure can be arranged below the encapsulation.

In another configuration, the electronic component can furthermore include an electrically active region including the layer to be protected against moisture.

In another configuration, the carrier can have a depression, wherein at least part of the electrically active region of the electronic component is arranged in the depression.

In another configuration, at least part of the substrate can be arranged in a depression.

In another configuration, the electronic component can be designed as a light-emitting electronic component. In various embodiments, the electronic component can be designed for example as a light-emitting electronic semiconductor component, in particular as a light-emitting diode.

In another configuration, the electronic component can be designed as an organic light-emitting diode.

In another configuration, the electronic component can be designed as a solar cell, for example as an organic solar cell, for example as a flexible organic solar cell.

In various embodiments, a method for producing an electronic component is provided. The method can include forming a layer to be protected against moisture; forming a moisture barrier layer arranged at least partly on or above and/or below the layer to be protected, wherein the moisture barrier layer has a plurality of layers composed of the same material having different stoichiometric compositions.

In one configuration of the method, the layers of the plurality of layers can be formed by means of a deposition method. By way of example, the deposition method can be a chemical vapor deposition (CVD) method.

In another configuration of the method, the vapor deposition method can be a plasma enhanced chemical vapor deposition (PECVD) method. By way of example, in this case, a plasma can be generated in a volume above and/or around the electronic component. At least two gaseous starting compounds are fed to the volume and excited to react with one another.

In various embodiments, at least one inert gas can be fed to the volume. The inert gas can be argon or helium, for example.

In another embodiment, the at least one inert gas can be fed in excess.

In one embodiment of the method, ammonia and silane for forming silicon nitride can be fed to the volume. By way of example, the ammonia can be fed in excess. In a further embodiment, the respective stoichiometric composition of the respective layer of the moisture barrier layer can be determined by the concentration of silane.

The moisture barrier layer according to the present disclosure may be formed for example at a temperature in a range of from room temperature (that is to say a temperature range of approximately 15° C. to approximately 25° C.) to approximately 400° C., for example at a temperature in a range of from room temperature to approximately 200° C.

In another embodiment of the method, tetraethyl orthosilicate (TEOS) or N₂O for forming silicon oxide can be fed to the volume. By way of example, the ammonia can be fed in excess. In a further embodiment, the respective stoichiometric composition of the respective layer of the moisture barrier layer can be determined by the concentration of tetraethyl orthosilicate (TEOS).

The moisture barrier layer can be formed for example at a temperature in a range of from approximately room temperature to approximately 400° C., for example at a temperature in a range of from room temperature to approximately 200° C.

The degree of amorphicity of the silicon nitride and/or of the silicon oxide can be implemented by the choice of suitable starting compounds, temperatures, plasma conditions and/or gas pressures.

In another configuration, the vapor deposition method can be designed as a plasmaless vapor deposition method (plasmaless chemical vapor deposition (PLCVD)).

In another configuration, the deposition method can be designed as an atomic layer deposition (ALD) method.

In another configuration, the atomic layer deposition method can be designed as a plasma enhanced atomic layer deposition (PEALD) method.

In another configuration, the atomic layer deposition method can be designed as a plasmaless atomic layer deposition (PLALD) method.

If the electronic component includes an LED, PD, SC and/or a TFT, the one or the plurality of functional layers can include an epitaxial layer sequence, an epitaxially grown semiconductor layer sequence, or can be embodied as such. In this case, the semiconductor layer sequence can include for example a III-V compound semiconductor on the basis of InGaAlN, InGaAlP and/or AlGaAs and/or a II-VI compound semiconductor including one or more of the elements Be, Mg, Ca and Sr and one or more of the elements O, S and Se. By way of example, the II-VI compound semiconductor materials include ZnO, ZnMgO, CdS, ZnCdS and MgBeO.

In various embodiments, by way of example, an electronic component including one or a plurality of OLEDs, for example, and/or one or a plurality of LEDs can be embodied in particular as a lighting device or as a display and have an active luminous area embodied with a large area. “With a large area” can mean in this case that the electronic component has an area of greater than or equal to a few square millimeters, for example greater than or equal to one square centimeter, and for example greater than or equal to one square decimeter.

The abovementioned enumeration of the embodiments of the electronic component should be understood to be by way of example and not restrictive excessively restrictive. Rather, the electronic component can include further electronic elements and/or functional layer sequences that are known per se to the person skilled in the art.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a cross-sectional view of an electronic component designed as a light-emitting component in accordance with various embodiments;

FIG. 2 shows a cross-sectional view of an electronic component in accordance with various embodiments;

FIG. 3 shows a cross-sectional view of an electronic component in accordance with various embodiments;

FIG. 4 shows a cross-sectional view of an electronic component in accordance with various embodiments;

FIG. 5 shows a cross-sectional view of an electronic component in accordance with various embodiments;

FIG. 6 shows a cross-sectional view of an electronic component in accordance with various embodiments; and

FIG. 7 shows a cross-sectional view of an electronic component in accordance with various embodiments.

### DETAILED DESCRIPTION

In the following detailed description, reference is made to the accompanying drawings, which form part of this description and show for illustration purposes specific embodiments in which the disclosure can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present disclosure. It goes without saying that the features of the various embodiments described herein can be combined with one another, unless specifically indicated otherwise. Therefore, the following detailed description should not be interpreted in a restrictive sense, and the scope of protection of the present disclosure is defined by the appended claims. The schematic drawings in the figures serve merely for illustrating the inventive concept and are not depicted as true to scale.

In the context of this description, the terms “connected” and “coupled” are used to describe both a direct and an indirect connection and a direct or indirect coupling. In the figures, identical or similar elements are provided with identical reference signs, insofar as this is expedient.

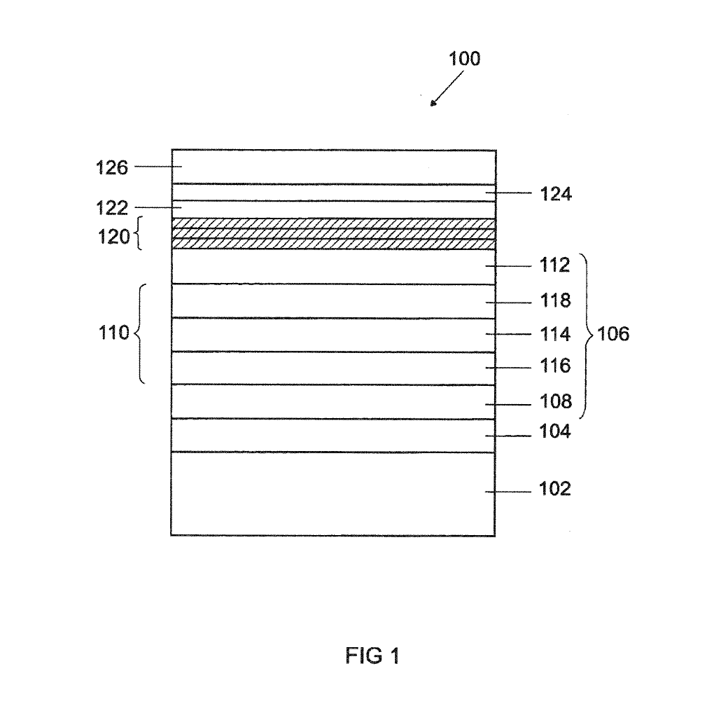

FIG. 1 shows a cross-sectional view of an electronic component 100, for example embodied as a light-emitting component 100, for example as an organic light-emitting diode (OLED) 100, in accordance with various embodiments.

The electronic component 100 can have a substrate 102. The substrate 102 can serve for example as a carrier or carrier element 102 for electronic elements or layers, for example light-emitting elements. By way of example, the substrate 102 can include or be formed from glass, quartz, and/or a semiconductor material or any other suitable material. Furthermore, the substrate 102 can include or be formed from a plastic film or a laminate including one or including a plurality of plastic films. The plastic can include or be formed from one or more polyolefins (for example high or low density polyethylene (PE) or polypropylene (PP)). Furthermore, the plastic can include or be formed from polyvinyl chloride (PVC), polystyrene (PS), polyester and/or polycarbonate (PC), polyethylene terephthalate (PET), polyether sulfone (PES) and/or polyethylene naphthalate (PEN). The substrate 102 can include one or more of the materials mentioned above. The substrate 102 can be embodied as translucent or even transparent. Furthermore, the substrate can be a (for example flexible) metal film (for example including or consisting of at least one of the materials aluminum, copper, steel, etc.).

In various embodiments, the term “translucent” or “translucent layer” can be understood to mean that a layer is transmissive to light, for example to the light generated by the light-emitting component, for example in one or more wavelength ranges, for example to light in a wavelength range of visible light (for example at least in a partial range of the wavelength range of from 380 nm to 780 nm). By way of example, in various embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, in various embodiments, “transparent” should be regarded as a special case of “translucent”.

For the case where, for example, a light-emitting monochromatic or emission spectrum-limited electronic component is intended to be provided, it suffices for the optically translucent layer structure to be translucent at least in a partial range of the wavelength range of the desired monochromatic light or for the limited emission spectrum.

In various embodiments, the organic light-emitting diode 100 (or else the light-emitting components in accordance with the embodiments that have been described above or will be described below) can as a bottom emitter or a top emitter or a top and bottom emitter. A top and bottom emitter can also be designated as an optically transparent component, for example a transparent organic light-emitting diode.

In various embodiments, a barrier layer 104 can optionally be arranged on or above the substrate 102. The barrier layer 104 can include or consist of one or more of the following materials: aluminum oxide, zinc oxide, zirconium oxide, titanium oxide, hafnium oxide, tantalum oxide, lanthanium oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer 104 can have a layer thickness in a range of approximately 0.1 nm (one atomic layer) to approximately 5000 nm, for example a layer thickness in a range of approximately 10 nm to approximately 200 nm, for example a layer thickness of approximately 40 nm.

An electrically active region 106 of the light-emitting component 100 can be arranged on or above the barrier layer 104. The electrically active region 106 can be understood as that region of the light-emitting component 100 in which an electric current for the operation of the light-emitting component 100 flows. In various embodiments, the electrically active region 106 can have a first electrode 108, a second electrode 112 and an organic functional layer structure 110, as will be explained in even greater detail below.

In this regard, in various embodiments, the first electrode 108 (for example in the form of a first electrode layer 108) can be applied on or above the barrier layer 104 (or, if the barrier layer 104 is not present, on or above the substrate 102). The first electrode 108 (also designated hereinafter as bottom electrode 108) can be formed from an electrically conductive material, such as, for example, a metal or a transparent conductive oxide (TCO) or a layer stack including a plurality of layers of the same metal or different metals and/or the same TCO or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GalnO₃, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped. These materials can be used in the same way in the embodiments described below.

In various embodiments, the first electrode 108 can include a metal; for example Ag, Pt, Au, Mg, Al, Ba, In, Ag, Au, Mg, Ca, Sm or Li, and compounds, combinations or alloys of these materials. These materials can be used in the same way in the embodiments described below.

In various embodiments, the first electrode 108 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers. These materials can be used in the same way in the embodiments described below.

In various embodiments, the first electrode 108 can provide one or a plurality of the following materials as an alternative or in addition to the abovementioned materials: networks composed of metallic nanowires and nanoparticles, for example composed of Ag; networks composed of carbon nanotubes; graphene particles and graphene layers; networks composed of semiconducting nanowires. These materials can be used in the same way in the embodiments described below.

Furthermore, the first electrode 108 can include electrically conductive polymers or transition metal oxides or transparent electrically conductive oxides.

In various embodiments, the first electrode 108 and the substrate 102 can be formed as translucent or transparent. In the case where the first electrode 108 is formed from a metal, the first electrode 108 can have for example a layer thickness of less than or equal to approximately 25 nm, for example a layer thickness of less than or equal to approximately 20 nm, for example a layer thickness of less than or equal to approximately 18 nm. Furthermore, the first electrode 108 can have for example a layer thickness of greater than or equal to approximately 10 nm, for example a layer thickness of greater than or equal to approximately 15 nm. In various embodiments, the first electrode 108 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case where the first electrode 108 is formed from a transparent conductive oxide (TCO), the first electrode 108 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case where the first electrode 108 is formed from, for example, a network composed of metallic nanowires, for example composed of Ag, which can be combined with conductive polymers, a network composed of carbon nanotubes which can be combined with conductive polymers, or from graphene layers and composites, the first electrode 108 can have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm. The first electrode 108 can be formed as an anode, that is to say as a hole-injecting electrode, or as a cathode, that is to say as an electron-injecting electrode.

The first electrode 108 can have a first electrical terminal, to which a first electrical potential (provided by an energy source (not illustrated), for example a current source or a voltage source) can be applied. Alternatively, the first electrical potential can be applied to the substrate 102 and then be fed indirectly to the first electrode 108 via said substrate. The first electrical potential can be, for example, the ground potential or some other predefined reference potential.

Furthermore, the electrically active region 106 of the light-emitting component 100 can have an organic electroluminescent layer structure 110, which is applied on or above the first electrode 108.

The organic electroluminescent layer structure 110 can contain one or a plurality of emitter layers 114, for example including fluorescent and/or phosphorescent emitters, and one or a plurality of hole-conducting layers 116 (also designated as hole transport layer(s) 116). In various embodiments, one or a plurality of electron-conducting layers 118 (also designated as electron transport layer(s) 118) can alternatively or additionally be provided.

Examples of emitter materials which can be used in the light-emitting component 100 in accordance with various embodiments for the emitter layer(s) 114 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl(2,2′)bipyridine]ruthenium(III) complex) and blue fluorescent DPAVBi (4,4-bis[4-(di-p-tolylamino) styryl]biphenyl), green fluorescent TTPA (9,10-bis[N,N-di(p-tolyfl)amino]anthracene) and red fluorescent DCM2 (4-dicyanomethylene)-2-methyl-6-julolidyl-9-enyl-4H-pyran) as non-polymeric emitters. Such non-polymeric emitters can be deposited by means of thermal evaporation, for example. Furthermore, it is possible to use polymer emitters, which can be deposited, in particular, by means of a wet-chemical method such as spin coating, for example. These materials can be used in the same way in the embodiments described below.

The emitter materials can be embedded in a matrix material in a suitable manner.

It should be pointed out that other suitable emitter materials are likewise provided in other embodiments.

The emitter materials of the emitter layer(s) 114 of the light-emitting component 100 can be selected for example such that the light-emitting component 100 emits white light. The emitter layer(s) 114 can include a plurality of emitter materials that emit in different colors (for example blue and yellow or blue, green and red); alternatively, the emitter layer(s) 114 can also be constructed from a plurality of partial layers, such as a blue fluorescent emitter layer 114 or blue phosphorescent emitter layer 114, a green phosphorescent emitter layer 114 and a red phosphorescent emitter layer 114. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary and secondary radiation.

The organic electroluminescent layer structure 110 can generally include one or a plurality of electroluminescent layers. The one or the plurality of electroluminescent layers can include organic polymers, organic oligomers, organic monomers, organic small, non-polymeric molecules (“small molecules”) or a combination of these materials. By way of example, the organic electroluminescent layer structure 110 can include one or a plurality of electroluminescent layers embodied as a hole transport layer 116, so as to enable for example in the case of an OLED an effective hole injection into an electroluminescent layer or an electroluminescent region. Alternatively, in various embodiments, the organic electroluminescent layer structure 110 can include one or a plurality of functional layers embodied as an electron transport layer 118, so as to enable for example in an OLED an effective electron injection into an electroluminescent layer or an electroluminescent region. By way of example, tertiary amines, carbazo derivatives, conductive polyaniline or polyethylene dioxythiophene can be used as material for the hole transport layer 116. In various embodiments, the one or the plurality of electroluminescent layers can be embodied as an electroluminescent layer. These materials can be used in the same way in the embodiments described below.

In various embodiments, the hole transport layer 116 can be applied, for example deposited, on or above the first electrode 108, and the emitter layer 114 can be applied, for example deposited, on or above the hole transport layer 116. In various embodiments, the electron transport layer 118 can be applied, for example deposited, on or above the emitter layer 114.

In various embodiments, the organic electroluminescent layer structure 110 (that is to say for example the sum of the thicknesses of hole transport layer(s) 116 and emitter layer(s) 114 and electron transport layer(s) 118) can have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 110 can have for example a stack of a plurality of organic light-emitting diodes (OLEDs) arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic electroluminescent layer structure 110 can have for example a stack of two, three or four OLEDs arranged directly one above another, in which case for example the organic electroluminescent layer structure 110 can have a layer thickness of a maximum of approximately 3 μm.

The light-emitting component 100 can optionally generally include further organic functional layers, for example arranged on or above the one or the plurality of emitter layers 114 or on or above the electron transport layer(s) 118, which serve to further improve the functionality and thus the efficiency of the light-emitting component 100.

The second electrode 112 (for example in the form of a second electrode layer 112) can be applied on or above the organic electroluminescent layer structure 110 or, if appropriate, on or above the one or the plurality of further organic functional layers.

In various embodiments, the second electrode 112 can include or be formed from the same materials as the first electrode 108, metals being particularly suitable in various embodiments.

In various embodiments, the second electrode 112 (for example for the case of a metallic second electrode 112) can have for example a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 112 can generally be formed in a similar manner to the first electrode 108, or differently than the latter. In various embodiments, the second electrode 112 can be formed from one or more of the materials and with the respective layer thickness, as described above in connection with the first electrode 108. In various embodiments, both the first electrode 108 and the second electrode 112 are formed as translucent or transparent. Consequently, the light-emitting component 100 illustrated in FIG. 1 can be designed as a top and bottom emitter (to put it another way as a transparent light-emitting component 100).

The second electrode 112 can be formed as an anode, that is to say as a hole-injecting electrode, or as a cathode, that is to say as an electron-injecting electrode.

The second electrode 112 can have a second electrical terminal, to which a second electrical potential (which is different than the first electrical potential), provided by the energy source, can be applied. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

A moisture barrier layer 120, for example in the form of a barrier thin-film layer/thin-film encapsulation 120, can be formed on or above the second electrode 112 and thus on or above the electrically active region 106 having at least one layer to be protected against moisture, wherein the moisture barrier layer 120 includes a plurality of layers composed of the same material having different stoichiometric compositions.

In the context of this application, a moisture barrier layer or a “barrier thin film” 120 can be understood to mean, for example, a layer structure which is suitable for forming a barrier against chemical impurities or atmospheric substances, in particular against water (moisture) and oxygen. In other words, the barrier thin-film layer 120 is formed in such a way that OLED-damaging substances such as water, oxygen or solvent cannot penetrate through it or at most very small proportions of said substances can penetrate through it.

In other words, in accordance with one configuration, the moisture barrier layer 120 can be formed as a layer stack. The moisture barrier layer 120 or one or a plurality of layers of the moisture barrier layer 120 can be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range can be deposited.

In accordance with one configuration, in the case of the moisture barrier layer 120, all the layers of the plurality of layers can be formed by means of an atomic layer deposition method. A layer sequence including only ALD layers can also be designated as a “nanolaminate”.

In accordance with an alternative configuration, in the case of a moisture barrier layer 120, at least one or more layers of the plurality of layers of the moisture barrier layer 120 can be deposited by means of a different deposition method than an atomic layer deposition method, for example by means of a vapor deposition method.

In accordance with one configuration, the moisture barrier layer 120 can have for example a layer thickness in a range of approximately 100 nm to approximately 100 μm, for example in a range of approximately 400 nm to approximately 20 μm, for example in a range of approximately 100 nm to approximately 250 nm.

In various embodiments, each layer of the plurality of layers can have a layer thickness of approximately 250 nm.

In various embodiments, a first layer of the plurality of layers can have a layer thickness of approximately 100 nm and at least one further layer can have a layer thickness of approximately 200 nm. By way of example, at least one first layer of the plurality of layers can have a layer thickness of approximately 100 nm and at least one further layer can have a layer thickness of approximately 250 nm.

In accordance with one configuration in which the moisture barrier layer 120, all the layers of the plurality of layers can have the same layer thickness. In accordance with another configuration, the individual layers of the moisture barrier layer 120 can have different layer thicknesses. In other words, at least one of the layers can have a different layer thickness than one or more other layers.

In accordance with one configuration, the moisture barrier layer 120 or the individual layers of the moisture barrier layer 120 can be embodied as a translucent or transparent layer. In other words, the moisture barrier layer 120 (or the individual layers of the plurality of layers of the barrier thin-film layer 120) can consist of a translucent or transparent material (or a material combination that is translucent or transparent).

The plurality of layers can consist of silicon nitride, for example. In various embodiments, the silicon nitride can be amorphous. The silicon nitride can have a stoichiometric composition in accordance with the formula SiNₓ, wherein 0≦x<2 holds true for x. The setting of the degree of amorphicity or for setting the stoichiometry of the moisture barrier layer 120 can be effected for example by the choice of suitable starting compounds, temperatures, plasma conditions and/or gas pressures. By way of example, at least one inert gas can be fed in for the purpose of gas pressure setting. The at least one inert gas can include or be for example argon, for example helium. The inert gas can be fed in excess. By way of example, ammonia can be fed to the volume. The ammonia can be fed in excess for setting the degree of amorphicity or for setting the stoichiometry. In various embodiments, silane can be fed in. The respective stoichiometric composition of the respective layer of the moisture barrier layer 120 can be determined by the concentration of silane. The moisture barrier layer 120 can be formed at a temperature in a range of from approximately room temperature to approximately 400° C., for example at a temperature in a range of from approximately room temperature to approximately 200° C.

The plurality of layers of the moisture barrier layer 120 can consist of silicon dioxide. The silicon dioxide can be amorphous, for example. The setting of the degree of amorphicity or for setting the stoichiometry of the moisture barrier layer 120 can be effected by the choice of, for example, suitable starting compounds, temperatures, plasma conditions and/or gas pressures. By way of example, tetraethyl orthosilicate (TEOS) or N₂O can be fed in. The respective stoichiometric composition of the respective layer of the moisture barrier layer 120 can be determined by the concentration of tetraethyl orthosilicate (TEOS). The moisture barrier layer can be formed for example at a temperature in a range of from approximately room temperature to approximately 400° C., for example at a temperature in a range of from approximately room temperature to approximately 200° C.

In various embodiments, a low refractive index intermediate layer or low refractive index intermediate layer structure 122 (for example having one or a plurality of layers composed of the same material or different materials) can be arranged on or above the moisture barrier layer 120 and serves, for example in the case of a transparent light-emitting component 100, to increase the total transparency thereof.

The intermediate layer 122 or intermediate layer structure 122 can include at least one layer which (at a predefined wavelength (for example at a predefined wavelength in a wavelength range of 380 nm to 780 nm)) has a refractive index which is less than the refractive index of a cover (at the predefined wavelength) of the light-emitting component 100, as will be explained in even greater detail below. In various embodiments, the intermediate layer or the at least one layer of the intermediate layer structure 122 or the entire intermediate layer structure 122 can have a refractive index which is less than the refractive index of a cover of the light-emitting component 100, as will be explained in even greater detail below.

On or above the intermediate layer 122 or the intermediate layer structure 122, it is possible to provide an adhesive and/or a protective lacquer 124, by means of which, for example, a cover 126 (for example a glass cover 126) is fixed, for example adhesively bonded, on the intermediate layer 122 or the intermediate layer structure 122. In various embodiments, the optically translucent layer composed of adhesive and/or protective lacquer 124 can have a layer thickness of greater than 1 μm, for example a layer thickness of several μm. In various embodiments, the adhesive can include or be a lamination adhesive.

In various embodiments, light-scattering particles can also be embedded into the layer of the adhesive (also designated as adhesive layer), which particles can lead to a further improvement in the color angle distortion and the coupling-out efficiency. In various embodiments, the light-scattering particles provided can be dielectric scattering particles, for example, such as metal oxides, for example, such as e.g. silicon oxide (SiO₂), zinc oxide (ZnO), zirconium oxide (ZrO₂), indium tin oxide (ITO) or indium zinc oxide (IZO), gallium oxide (Ga₂Oₐ), aluminum oxide, or titanium oxide. Other particles may also be suitable provided that they have a refractive index that is different than the effective refractive index of the matrix of the translucent layer structure, for example air bubbles, acrylate, or hollow glass beads. Furthermore, by way of example, metallic nanoparticles, metals such as gold, silver, iron nanoparticles, or the like can be provided as light-scattering particles.

In various embodiments, between the second electrode 112 and the layer composed of adhesive and/or protective lacquer 124 a further electrically insulating layer (not shown), for example a further moisture barrier layer 120, can also be applied, for example SiN, for example having a layer thickness in a range of approximately 100 nm to approximately 100 μm, for example having a layer thickness in a range of approximately 400 nm to approximately 20 μm, in order to protect electrically unstable materials, during a wet-chemical process for example.

In various embodiments, the adhesive can be designed in such a way that it itself has a refractive index which is less than the refractive index of the cover 126. In this case, the adhesive itself illustratively forms the intermediate layer 122 or the intermediate layer structure 122 or a part thereof. Such an adhesive can be, for example, a low refractive index adhesive such as, for example, an acrylate having a refractive index of approximately 1.3. Furthermore, a plurality of different adhesives which form an adhesive layer sequence can be provided.

Furthermore, it should be pointed out that, in various embodiments, an adhesive 124 can also be completely dispensed with, for example in embodiments in which the cover 126, for example composed of glass, is applied to the intermediate layer 122 or the intermediate layer structure 122 by means of plasma spraying, for example.

In embodiments in which both an intermediate layer 122 or an intermediate layer structure 122 and an adhesive 124 are provided, the at least one layer of the layer structure can have a refractive index which is also less than the refractive index of the adhesive 124.

In various embodiments, the cover 126 and/or the adhesive 124 can have a refractive index (for example at a wavelength of 633 nm) of 1.55.

Furthermore, in various embodiments, one or a plurality of antireflective layers (for example combined with the moisture barrier layer 120, for example the thin-film encapsulation 120) can additionally be provided in the light-emitting electronic component 100.

By way of example, the moisture barrier layers 120 described here in various embodiments can keep an electronic component 100, which is sensitive to moisture and/or oxygen (corrosion) at least in regions, impermeable to moisture and oxygen for longer than 900 hours, at a temperature of greater than or equal to 60° C. and a relative air humidity of greater than or equal to 90% or else under one of the conditions mentioned above.

The barrier effect of the moisture barrier layer 120 composed of silicon nitride can thus be considerably improved if at least two or preferably a plurality of layers composed of silicon nitride having different properties, for example different layer stresses, are deposited one above another, for example with fluid transitions between the layers. The fact of different stresses of the layers to be combined makes possible since, as a result, particles/unevennesses on the surface can be reshaped in a stress-free manner and, as a result, the moisture barrier layer 120 according to the present disclosure exhibits a significantly higher barrier effect with respect to, for example, OLED-harmful substances such as, for example, water or oxygen. Moreover, for example, a moisture barrier layer 120 produced by means of CVD can be adapted in an optimized manner to strains of the support or of the subsequent layers, in order to produce an overall layer that is as free of stress as possible. Moisture barrier layers 120 improved in this way can additionally be combined with further barrier layers, for example ALD layers.

| | Total layer | Average | |
|---|---|---|---|
| | thickness | “dark spot density” | Stress |
| Stack | [nm] | [T0] | [a.u.] |
| P1 (x nm) | X | 12 | y1 |
| P2 (x nm) | X | 9 | y2 (y1 > y2) |
| P1 (x/2 nm) | X | 4 | y3 (y1 > y3 > y2) |
| P2 (x/2 nm) | | | |
| P2 (x/2 nm) | X | 5 | y4 (y1 > y4 > y2) |
| P1 (x/2 nm) | | | |
| P2 (x/4 nm) | X | 5 | y5 (y1 > y5 > y2) |
| P1 (x/4 nm) | | | |
| P2 (x/4 nm) | | | |
| P1 (x/4 nm) | | | |

In the table above, X denotes the layer thickness and Y denotes the stress.

Furthermore, in the table above, the dark spot density relates to components having a luminous area of approximately 1.7 cm².

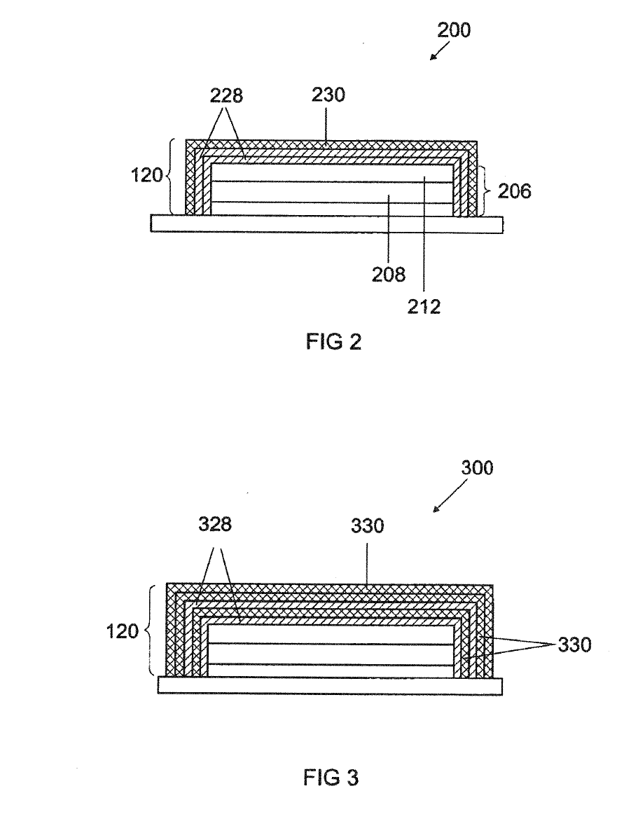

FIG. 2 shows a cross-sectional view of an electronic component 200 in accordance with various embodiments.

The electronic component 200 can include a substrate 202, on which an electrically active region 206 include, which is indicated purely schematically in FIG. 2 and can be embodied for example in accordance with the examples present in FIG. 1.

The electrically active region 206 can be understood as that region of the electronic component 200 in which an electric current for the operation of the electronic component 200 flows. In various embodiments, the electrically active region 206 can include a first electrode 208 and a second electrode 212. In this case, the first electrode 208 can be an anode, for example. In this case, the second electrode 212 can be a cathode, for example.

In accordance with various embodiments, the electrically active region 206 can include at least one layer to be protected against moisture, on or above which the moisture barrier layer 120, which includes a plurality of layers composed of the same material having different stoichiometric compositions, can be arranged at least in regions.

The plurality of the layers or layers of the moisture barrier layer 120 can include for example a first layer 228 composed of silicon nitride, a second layer 228 composed of silicon nitride and arranged on said first layer, and a further layer 230 composed of silicon oxide and arranged on said second layer 228. The layers can be embodied in accordance with the embodiments described in FIG. 1 and can have for example different layer thicknesses, for example a layer thickness in a range of approximately 5 nm to approximately 5 μm. The layer thicknesses can be produced for example alternately with high or low layer stress.

FIG. 3 shows a cross-sectional view of an electronic component 300 in accordance with various embodiments.

In various embodiments, the moisture barrier layer 120 can have for example a stacked construction including a layer 328 consisting of silicon nitride, a layer 330 consisting of silicon oxide, a further layer 328 composed of silicon nitride and arranged on the layer 330, and two further layers 330 composed of silicon oxide and arranged on the second layer 328, wherein the layer stress can in each case be low or high, wherein a setting, for example reduction, of the layer stress can be brought about by a suitable choice of the deposition parameters. Through the choice of the process parameters, it is possible to optimize the covering of edges or unevennesses of surfaces on which the moisture barrier layer 120 is arranged by the deposition of layers, including of different compositions, and it is thus possible to improve the service life of the moisture barrier layer 120 and thus of the electronic component 300.

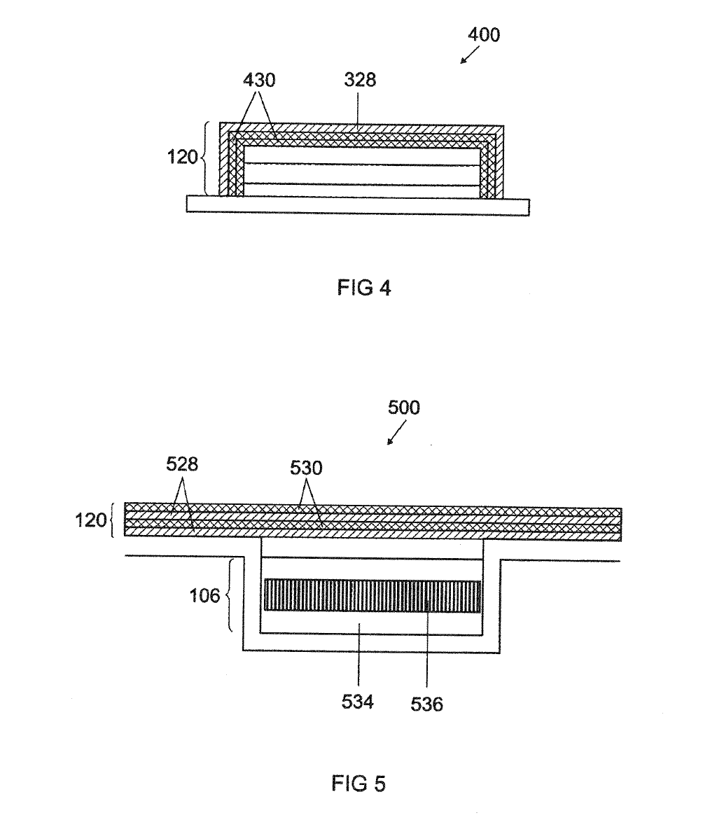

FIG. 4 shows a cross-sectional view of an electronic component 400 in accordance with various embodiments.

In various embodiments, the electronic component 400 can have a stacked construction having a layer 430 consisting of silicon oxide or including silicon oxide, a layer 430 composed of silicon oxide and a layer 428 composed of silicon nitride. In this case, the choice of the material of the respective layer can be made for example according to the optical or insulating properties of the material.

FIG. 5 shows a cross-sectional view of an electronic component 500, for example embodied as an LED or a (for example top-emitting) OLED, in accordance with various embodiments.

The electrically active region 106 can be arranged in a depression 534. By way of example, an electrically active region 106 and a light-emitting GaN layer 536 can be arranged in the depression and have a stacked construction having a layer 528 consisting of silicon nitride, a layer 530 consisting of silicon oxide, a further layer 528 composed of silicon nitride and arranged on the layer 530, and two further layers 530 composed of silicon oxide and arranged on the second layer 528, wherein the layer stress can be in each case low or high, wherein a setting, for example reduction, of the layer stress can be brought about by a suitable choice of the deposition parameters. Through the choice of the process parameters, it is possible to optimize the covering of edges or unevennesses of surfaces on which the moisture barrier layer 120 is arranged by the deposition of layers, including of different compositions, and it is thus possible to improve the service life of the moisture barrier layer 120 and thus of the electronic component 500.

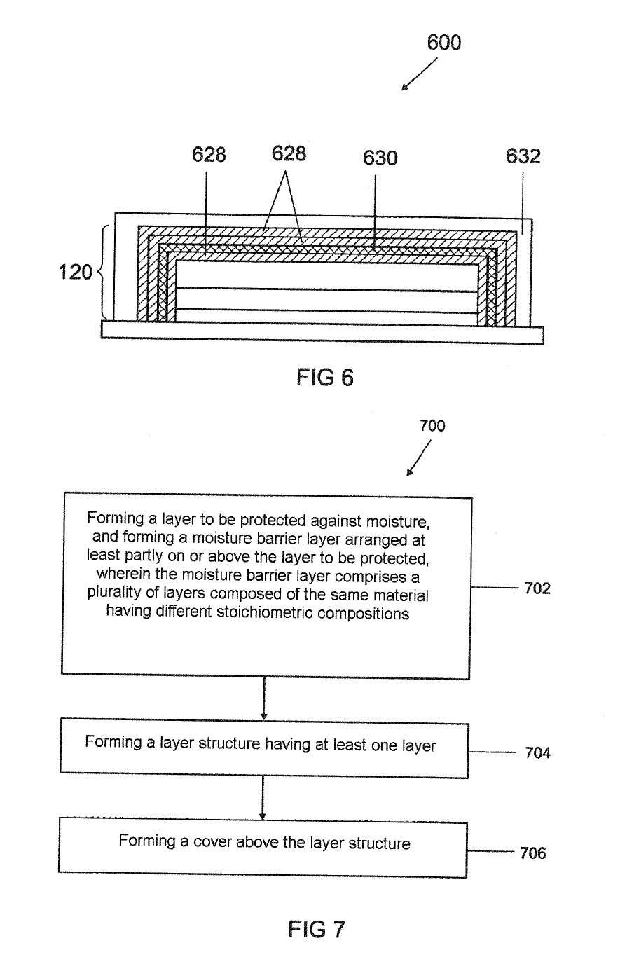

FIG. 6 shows a cross-sectional view of an electronic component in accordance with various embodiments.

An electronic component 600 which can be configured according to one of the embodiments mentioned above and is illustrated only purely schematically can additionally include an encapsulation 632, which can be arranged above the layers or the plurality of layers of the moisture barrier layer 120. FIG. 6 shows by way of example a stacked construction of the layers including a layer 628 composed of silicon nitride, a layer 632 composed of silicon oxide and a plurality of layers 628 composed of silicon nitride, wherein the layer stress can be in each case low or high, wherein a setting, for example reduction, of the layer stress can be brought about by a suitable choice of the deposition parameters. Through the choice of the process parameters, it is possible to optimize the covering of edges or unevennesses of surfaces on which the moisture barrier layer 120 is arranged by the deposition of layers, including of different compositions, and it is thus possible to improve the service life of the moisture barrier layer 120 and thus of the electronic component 600.

FIG. 7 shows a flow chart 700 illustrating a method for producing a light-emitting component in accordance with various embodiments.

In 702 an electrically active region 106 is formed, wherein a first electrode 108 and a second electrode 112 are formed, and wherein an organic functional layer structure is formed between the first electrode and the second electrode. Furthermore, in 704 a layer structure having at least one layer can be formed above the electrically active region.

The various layers, for example the intermediate layer 122 or intermediate layer structure 122, the electrodes 108, 112 and the other layers of the electrically active region 106 such as, for example, the organic functional layer structure 114, the hole transport layer(s) 116 or the electron transport layer(s) 118 can be applied, for example deposited, by means of various processes, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

The method furthermore includes forming at least one layer to be protected against moisture, and forming a moisture barrier layer 120, which is arranged at least partly on or above the layer to be protected and the moisture barrier layer includes a plurality of layers composed of the same material having different stoichiometric compositions.

The layers of the plurality of layers be formed by means of a deposition method. The deposition method can be a chemical vapor deposition (CVD) method. The vapor deposition method can be a plasma enhanced chemical vapor deposition (PECVD) method. By way of example, a plasma can be generated in a volume above and/or around the electrical component, and wherein at least two gaseous starting compounds can be fed to the volume and excited to react with one another. By way of example, at least one inert gas can be fed to the volume, by means of which at least one inert gas for example the gas pressure can be set, for example for producing layers having different layer stresses. The inert gas can be for example argon, for example helium. The at least one inert gas can be fed in excess, for example. In order to produce silicon nitride layers, ammonia, for example, can be fed to the volume as a starting compound. The ammonia can be fed in excess for example for setting the stoichiometry of the moisture barrier layer 120. In order to produce silicon nitride layers, silane can be fed to the volume as a further starting compound. The respective stoichiometric composition of the respective layer of the moisture barrier layer 120 can be determined by the concentration of silane. For setting for example a desired degree of amorphicity or other properties of the respective layer, for example the layer stress of the respective layer of the moisture barrier layer 120, the moisture barrier layer can be formed at a temperature in a range of from approximately room temperature to approximately 400° C., for example at a temperature in a range of from approximately room temperature to approximately 200° C. The temperature for the respective layer can be set in the process.

In order to produce silicon oxide layers, tetraethyl orthosilicate (TEOS) or N₂O, for example, can be fed to the volume.

The respective stoichiometric composition of the respective layer of the moisture barrier layer 120 can be determined by the concentration of tetraethyl orthosilicate (TEOS) or N₂O. Taking account of the amorphicity or other properties of the respective layer, for example the layer stress of the respective layer of the moisture barrier layer 120, the moisture barrier layer can be formed at a temperature in a range of from approximately room temperature to approximately 400° C., for example at a temperature in a range of from approximately room temperature to approximately 200° C., wherein the temperature for the respective layer can be set.

The vapor deposition method can be designed for example as a plasmaless chemical vapor deposition (PLCVD) method. The deposition method can be designed for example as an atomic layer deposition (ALD) method. The atomic layer deposition method can be designed as plasma enhanced atomic layer deposition (PEALD). The atomic layer deposition method can be designed as a plasmaless atomic layer deposition (PLALD) method.

In various embodiments, a plasma enhanced chemical vapor deposition (PE-CVD) method can be used as CVD method. In this case, a plasma can be generated in a volume above and/or around the element to which the layer to be applied is intended to be applied, wherein at least two gaseous starting compounds are fed to the volume, said compounds being ionized in the plasma and excited to react with one another. The generation of the plasma can make it possible that the temperature to which the surface of the element is to be heated in order to make it possible to produce the dielectric layer, for example, can be reduced in comparison with a plasmaless CVD method. That may be advantageous, for example, if the element, for example the light-emitting electronic component to be formed, would be damaged at a temperature above a maximum temperature. The maximum temperature can be approximately 120° C. for example in the case of a light-emitting electronic component to be formed in accordance with various embodiments, such that the temperature at which the dielectric layer for example is applied can be less than or equal to 120° C. and for example less than or equal to 80° C.

Furthermore, it can be provided that after forming the electrically active region 106 and before forming the cover 104, the optical transparency of the structure having the electrically active region is measured. The intermediate layer or intermediate layer structure can then be formed depending on the measured optical transparency, such that a desired optical target transparency of the structure having the electrically active region and of the intermediate layer or intermediate layer structure is obtained (in this regard, by way of example, the layer thickness and/or a choice of material of the intermediate layer or intermediate layer structure can be adapted).

In various embodiments, it was recognized that the transparency of a light-emitting component such as an OLED, for example, can be increased by the use of a very thin layer having a low refractive index in comparison with the adhesive and cover glass (both of which usually have approximately the same refractive index). In various embodiments, the layer thickness is in a range of 50 nm to 150 nm. As explained above, the transparency of the light-emitting component can be significantly increased depending on the refractive index and the thickness of the layer. Optionally, it is possible to form a cover above the layer structure in 706, wherein the at least one layer of the layer structure has a refractive index which is lower than the refractive index of the cover. In various embodiments, such a low refractive index layer (i.e. for example having a refractive index of less than 1.5) can be introduced in the ongoing process flow as an additional layer for example on the encapsulation, for example the moisture barrier layer 120.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An electronic component comprising:
a layer to be protected against moisture; and
a moisture barrier layer arranged at least partly on or above and/or below the layer to be protected;
wherein the moisture barrier layer comprises a plurality of layers composed of the same material having different stoichiometric compositions.

2. The electronic component as claimed in claim 1, wherein the moisture barrier layer has a layer thickness in a range of approximately 10 nm to approximately 100 μm.

3. The electronic component as claimed in claim 1,
wherein the plurality of layers consists of silicon nitride.

4. The electronic component as claimed in claim 3, wherein the silicon nitride is amorphous.

5. The electronic component as claimed in claim 1,
wherein the plurality of layers consists of silicon dioxide.

6. The electronic component as claimed in claim 5, wherein the silicon dioxide is amorphous.

7. The electronic component as claimed in claim 1, further comprising:
a carrier, wherein the layer to be protected against moisture is arranged on or above the carrier; and
an encapsulation, wherein the encapsulation is arranged on or above the moisture barrier layer.

8. The electronic component as claimed in claim 1,
designed as a light-emitting electronic component.

9. The electronic component as claimed in claim 8, designed as a light-emitting diode.

10. The electronic component as claimed in claim 1,
designed as a solar cell.

11. A method for producing an electronic component, the method comprising:
forming a layer to be protected against moisture; and
forming a moisture barrier layer arranged at least partly on or above and/or below the layer to be protected;
wherein the moisture barrier layer has a plurality of layers composed of the same material having different stoichiometric compositions.

12. The method as claimed in claim 11,
wherein at least one inert gas is fed to the volume.

13. The method as claimed in claim 12,
wherein the at least one inert gas comprises or is argon and/or helium.

14. The electronic component as claimed in claim 8,
designed as an organic light-emitting diode.

15. The electronic component as claimed in claim 8,
designed as a flexible organic light-emitting diode.

16. The electronic component as claimed in claim 1,
designed as an organic solar cell.

17. The electronic component as claimed in claim 1,
designed as a flexible organic solar cell.
